(19) United States
(12) Patent Application Publication
(10) Pub. No.: US 2026/0040475 A1
(43) Pub. Date: Feb. 5, 2026

(54) SUBSTRATE STRUCTURE

(71) Applicant: TDK CORPORATION, Tokyo (JP)

(72) Inventors: Mitsuyoshi TAKAO, Tokyo (JP); Kouji KANEKO, Tokyo (JP); Shinya MOTOOKA, Tokyo (JP); Hiroshi KAMEYAMA, Tokyo (JP); Sanehito KEMMOTSU, Tokyo (JP)

(73) Assignee: TDK CORPORATION, Tokyo (JP)

(21) Appl. No.: 19/288,640

(22) Filed: Aug. 1, 2025

(30) Foreign Application Priority Data
Aug. 2, 2024 (JP) 2024-127702

(51) Int. Cl. H05K 7/14

(52) U.S. Cl. CPC H05K 7/1432

(57) ABSTRACT

In a substrate structure, an outer peripheral surface of a first positioning portion extends parallel to an extension direction in insertion parts inserted into each of first positioning holes. In this case, the insertion part of the first positioning hole of each substrate has a structure in which the outer peripheral surface of the first positioning portion is constant in the vertical direction. In this case, when the reference positions of the first positioning portion and the first positioning hole are set at the time of design, the reference setting can be easily performed. In addition, when the member is processed, the processing can be easily and accurately performed. As described above, it is possible to easily manufacture the substrate while accurately positioning the plurality of substrates.

### CROSS-REFERENCE TO RELATED APPLICATIONS

This application is based upon and claims the benefit of priority from Japanese Patent Applications No. 2024-127702, filed on 2 Aug. 2024, the entire content of which is incorporated herein by reference.

### TECHNICAL FIELD

The present disclosure relates to a substrate structure.

### BACKGROUND

Known in the art is a structure in which a plurality of positioning holes of a substrate are inserted with positioning protrusions provided on a base plate, as a substrate structure (for example, Japanese Patent Application Publication No. 2012-89757). In this substrate structure, the outer peripheral surface of the positioning protrusion has a taper shape that tapers off.

In the above-described substrate structure, the positioning protrusion positioning each of the substrates has a taper shape. In this case, in the insertion part of the positioning holes of the substrates, the position of the outer peripheral surface of the positioning protrusion changes in the vertical direction. In this case, it is likely to complicate reference setting in designing and be difficult to process the member with high accuracy. Therefore, there has been a demand for a substrate structure that can be easily manufactured while accurately positioning substrates.

According to one aspect of the present disclosure, there is provided a substrate structure enable to be easily manufactured while accurately positioning substrates.

### SUMMARY

A substrate structure according to an aspect of the present disclosure includes a base plate, three or more substrates, and a first positioning portion disposed to extend from the base plate and positioning a plurality of the substrates. Each of the plurality of substrates has a first positioning hole to be inserted with the first positioning portion. An outer peripheral surface of the first positioning portion extending parallel to an extension direction at each of insertion parts inserted into each of the first positioning holes.

The substrate structure includes the first positioning portion provided to extend from the base plate and positioning the plurality of substrates. In addition, each of the plurality of substrates has the first positioning hole inserted with the first positioning portion. Therefore, by inserting into the first positioning holes of the plurality of substrates with the first positioning portion, the plurality of substrates may be positioned based on the first positioning portion. Here, the outer peripheral surface of the first positioning portion extends parallel to the extension direction in the insertion parts inserted into each of the first positioning holes. In this case, the insertion part of the first positioning hole of each substrate has a structure in which the outer peripheral surface of the first positioning portion is constant in the vertical direction. In this case, when the reference positions of the first positioning portion and the first positioning hole are set in designing, the reference setting can be easily performed. In addition, when the member is processed, the processing can be easily and accurately performed. As described above, it is possible to easily manufacture and accurately position the substrates.

Each of the insertion parts in the first positioning portion may have the same diameter. In this case, design and processing are facilitated.

Each of the insertion parts in the first positioning portion may be formed in a stepped shape such that diameters increase sequentially from the distal end side. In this case, since the proximal end side of the base plate in the first positioning portion can be made thicker than the distal end side, the strength of the first positioning portion can be improved.

A distal end of the first positioning portion may be formed in a taper shape. In this case, the distal end of the first positioning portion may guide the first positioning hole of the substrate.

Each of the substrates may have a second positioning hole at a position different from the first positioning hole, a second positioning portion provided to extend from the base plate at a position different from the first positioning portion may be inserted into the second positioning hole. In this case, by inserting the second positioning portion into the second positioning hole of the substrate, the rotation of the substrate about the first positioning portion can be stopped at the second positioning portion.

Each of the second positioning holes may have the same shape and the same size. In this case, since the second positioning hole can be formed by the same design and processing method in each substrate, design and processing can be easily performed.

### BRIEF DESCRIPTION OF THE DRAWINGS

FIG. 1 is a side view of a power supply device including a substrate structure according to one embodiment of the present disclosure.

FIG. 2 is a perspective view of the substrate structure according to the present embodiment of the present disclosure.

FIG. 3 is an exploded perspective view of the substrate structure according to the present embodiment of the present disclosure.

FIG. 4 is a plan view of the substrate structure.

FIG. 5 is a schematic cross-sectional view of the substrate structure.

FIG. 6 is an enlarged view of the positioning portion and the positioning hole.

FIG. 7 is a schematic cross-sectional view of the modified substrate structure.

FIG. 8 is a schematic cross-sectional view of the modified substrate structure.

FIG. 9A shows the first positioning portion of the substrate structure according to the modified example, and FIG. 9B shows the first positioning portion of the substrate structure according to the comparative example.

### DETAILED DESCRIPTION

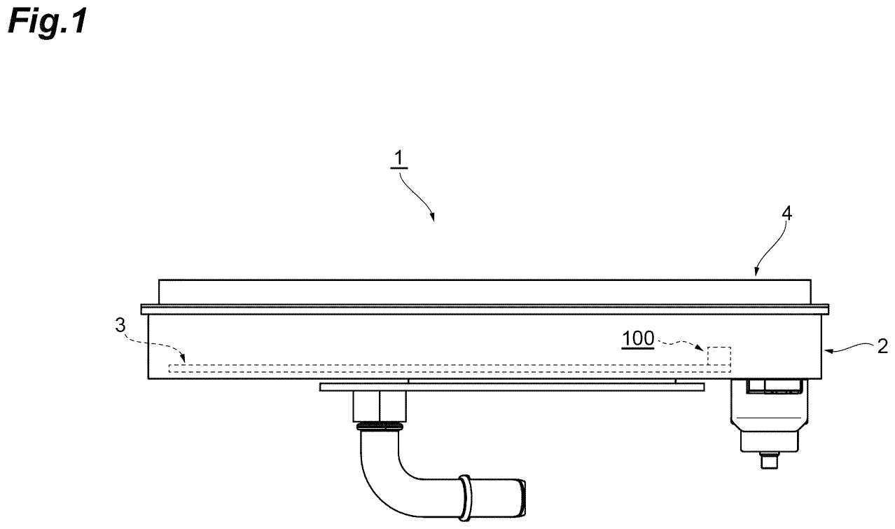

With reference to FIG. 1, a power supply device 1 including a substrate structure 100 according to the present embodiment is described. FIG. 1 is a side view of the power supply device 1 including the substrate structure 100. As shown in FIG. 1, the power supply device 1 includes a base plate 2 (a housing), three of more substrates 3, and a lid body 4. The power supply device 1 is assembled by fitting the lid body 4 onto the base plate 2 in a state where the substrates 3 are housed. The base plate 2 may be made of a die-cast alloy or the like. The power supply device 1 may be a unit including, for example, an AC/DC power supply or a DC/DC converter. The substrate structure 100 is provided in the power supply device 1. The overall shape of the power supply device 1 is not limited to that shown in FIG. 1. The position of the substrate structure 100 in the power supply device 1 is not particularly limited.

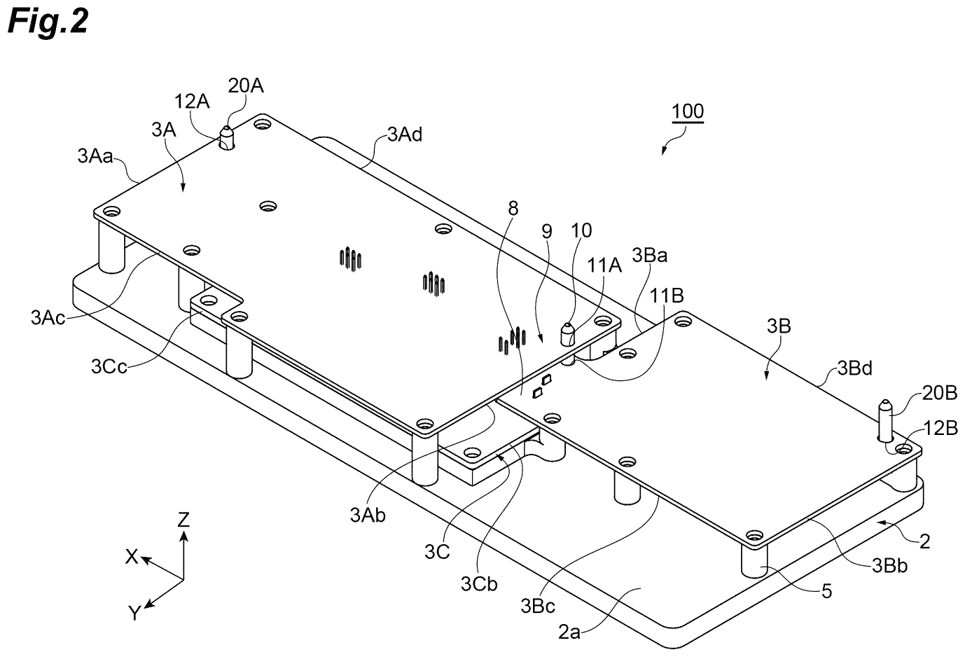

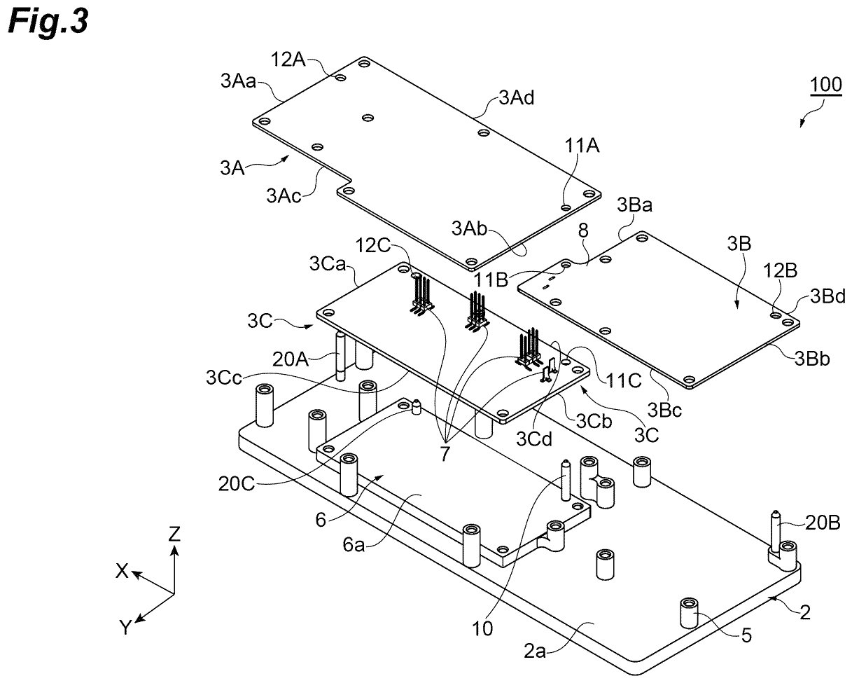

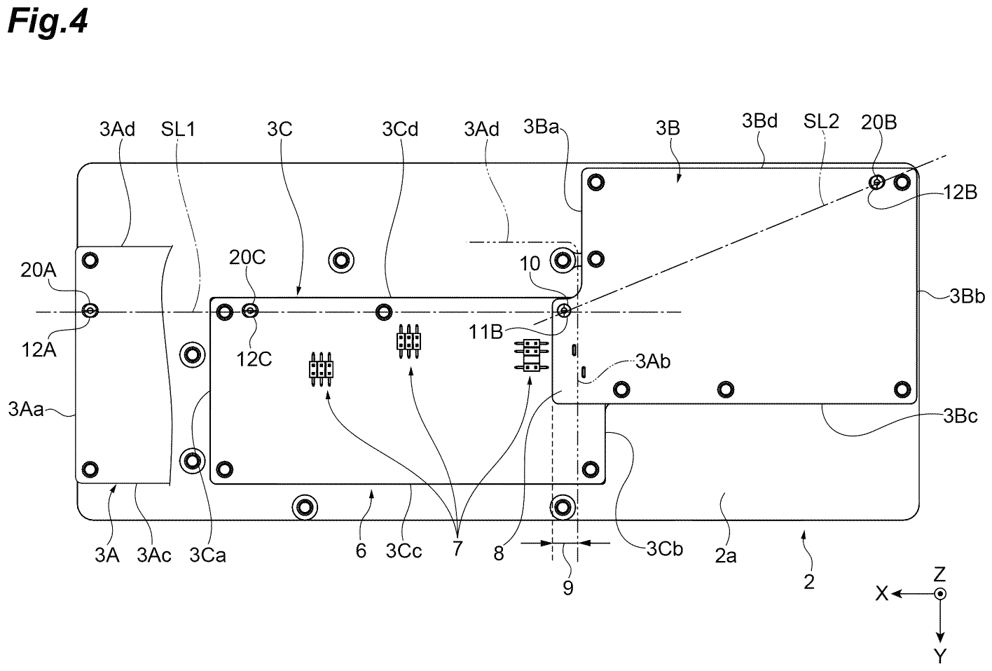

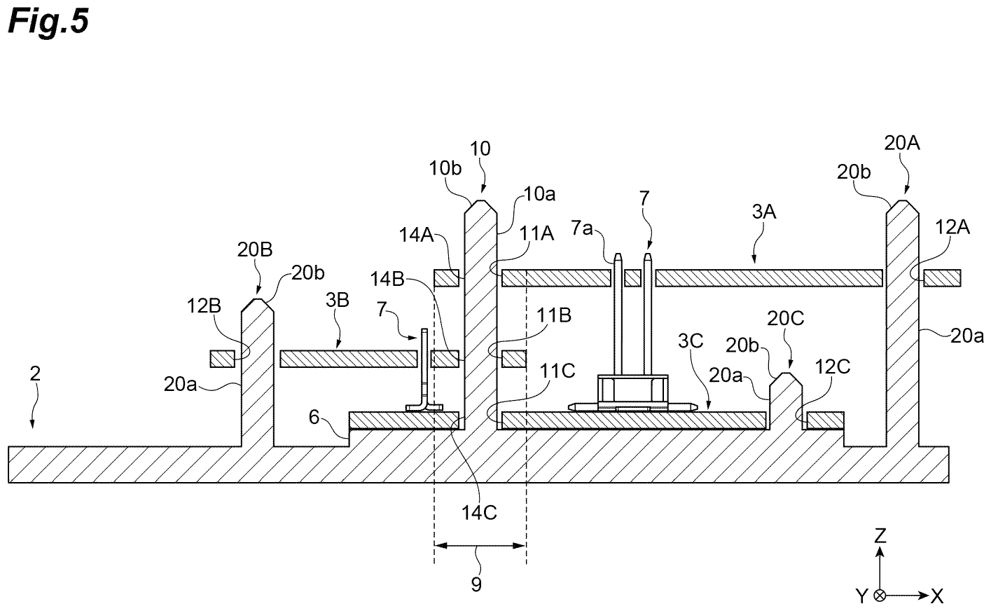

With reference to FIGS. 2 to 4, the structure of the substrate structure 100 is described. FIG. 2 is a perspective view of the substrate structure 100. FIG. 3 is an exploded perspective view of the substrate structure 100. FIG. 4 is a plan view of the substrate structure 100. In FIG. 4, a part of the substrate 3A is omitted. FIG. 5 is a schematic cross-sectional view of the substrate structure 100. The X-axis direction and the Y-axis direction are set and shown with respect to the bottom surface of the base plate 2 and the direction in which the substrate 3 (see FIG. 1) extends. The Z-axis direction is set to the bottom surface of the base plate 2 and the thickness direction of the substrate 3. In the present specification, the upper side is defined as the positive side in the Z-axis direction, and the lower side is defined as the negative side in the Z-axis direction. In the present specification, for convenience of description, words such as “up” and “down” may be used, but these do not limit the posture of the power supply device 1 and the substrate structure 100 during use. As shown in FIGS. 2 to 4, the substrate structure 100 includes the base plate 2 and the substrates 3A, 3B, and 3C.

The base plate 2 has an upper surface 2a extending parallel to the X-Y plane. The upper surface 2a of the base plate 2 is provided with a plurality of boss portions 5 for fixing the substrates 3A and 3B with screws, a step portion 6 for supporting and fixing the substrate 3C, a first positioning portion 10 to be described later, second positioning portions 20A, 20B, and 20C to be described later. An upper surface 6a of the step portion 6 extends parallel to the X-Y plane at a position higher than the upper surface 2a. On the upper surface 6a of the step portion 6, the substrate 3C is placed. In the upper surface 6a of the step portion 6, screw holes for screwing the substrate 3C are formed.

The substrates 3A, 3B, and 3C are plate-shaped members on which electronic components (not shown) are mounted. The substrate 3A is disposed at a position spaced upwardly from the upper surface 2a of the base plate 2. A control substrate that controls a switch element may be mounted on the substrate 3A. A power-system circuit including a switch element may be mounted on the substrate 3C. An output-circuit component including a smoother circuit may be mounted on the substrate 3B.

The substrate 3A has a substantially rectangular shape, and has edges 3Aa, 3Ab, 3Ac, and 3Ad on four sides. The edges 3Aa and 3Ab extend in the Y-axis direction and face each other in the X-axis direction. The edge 3Aa is disposed on the positive side in the X-axis direction, and the edge 3Ab is disposed on the negative side in the X-axis direction. The edges 3Ac and 3Ad extend in the X-axis direction and face each other in the Y-axis direction. The edge 3Ac is disposed on the positive side in the Y-axis direction, and the edge 3Ad is disposed on the negative side in the Y-axis direction. A portion of the edge 3Ac on the negative side in the X-axis direction protrudes to the positive side in the Y-axis direction. A through-hole through which a bolt fastened to the boss portion 5 is inserted is formed near each edge of the substrate 3A.

The substrate 3B is spaced upwardly from the upper surface 2a of the base plate 2 and is disposed at a position lower than the substrate 3A. The substrate 3B is vertically spaced from the substrate 3A and the substrate 3C. That is, the substrate structure 100 is different from a structure in which the substrates 3A, 3B, and 3C are laminated without a gap. The substrate 3B is disposed so as to be entirely adjacent to the substrate 3A on the negative side in the X-axis direction. The substrate 3B has a substantially rectangular shape, and has edges 3Ba, 3Bb, 3Bc, and 3Bd on four sides. The edges 3Ba and 3Bb extend in the Y-axis direction and face each other in the X-axis direction. The edge 3Ba is disposed on the positive side in the X-axis direction, and the edge 3Bb is disposed on the negative side in the X-axis direction. The edges 3Bc and 3Bd extend in the X-axis direction and face each other in the Y-axis direction. The edge 3Bc is disposed on the positive side in the Y-axis direction, and the edge 3Bd is disposed on the negative side in the Y-axis direction. The edge 3Bc is disposed on the negative side of the edge 3Ac of the substrate 3A in the Y-axis direction. The edge 3Bd is disposed on the negative side of the edge 3Ad of the substrate 3A in the Y-axis direction. A portion of the edge 3Ba on the negative side in the Y-axis direction is disposed on the negative side in the X-axis direction with respect to the edge 3Ab of the substrate 3A. On the other hand, in the edge 3Ba, a overhang portion 8 on the positive side in the Y-axis direction protrudes to the positive side in the X-axis direction, and is disposed on the positive side in the X-axis direction with respect to the edge 3Ab of the substrate 3A. A through hole for inserting a bolt fastened to the boss portion 5 is formed near each edge part of the substrates 3A and 3B.

The substrate 3C is placed on the upper surface 6a of the step portion 6. The substrate 3C is located generally below the substrate 3A. The substrate 3B has a substantially rectangular shape, and has edges 3Ca, 3Cb, 3Cc, and 3Cd on four sides. The edges 3Ca and 3Cb extend in the Y-axis direction and face each other in the X-axis direction. The edge 3Ca is disposed on the positive side in the X-axis direction, and the edge 3Cb is disposed on the negative side in the X-axis direction. The edges 3Cc and 3Cd extend in the X-axis direction and face each other in the Y-axis direction. The edge 3Cc is disposed on the positive side in the Y-axis direction, and the edge 3Cd is disposed on the negative side in the Y-axis direction. The edge 3Cc portion is disposed at substantially the same position as the region on the positive side in the X-axis direction of the edge 3Ac of the substrate 3A. The edge 3Cd is disposed on the positive side in the Y-axis direction with respect to the edge 3Ad and 3Bd of the substrates 3A and 3B. The edge 3Ca is disposed on the negative side of the edge 3Aa of the substrate 3A in the X-axis direction. The edge 3Ca is disposed on the positive side of the edge 3Ab of the substrate 3A in the X-axis direction. The edge 3Cb is disposed on the negative side in the X-axis direction with respect to the edges 3Ab and 3Ba of the substrates 3A and 3B. Through holes through which bolts fastened to the screw holes of the step portion are inserted are formed near the four corner portions of the substrate 3C. A plurality of a connection terminal 7 are provided on the substrate 3C. The upper end portion of the connection terminal may penetrate the substrate 3A to extend upward from the substrate 3A (see FIG. 2). The top of a pin 7a of the connection terminal 7 is lower than the first positioning portion 10.

According to the position relationship of the substrates 3A, 3B, and 3C as described above, the vicinity of the edge 3Ab of the substrate 3A, the vicinity of the overhang portion 8 of the edge 3Ba of the substrate 3B, and the vicinity of the edge 3Cb of the substrate 3C are configured as an overlapping portion 9 overlapping each other in the vertical direction (see FIGS. 4 and 5). The area of the portion where the substrate 3B overlaps the substrate 3A 3C is smaller than the area of the non-overlapping portion of the substrate 3B. In the base plate 2, the first positioning portion 10 is provided at a position corresponding to the overlapping portion 9. As shown in FIGS. 2 and 3, the first positioning portion 10 is provided so as to extend upward from the base plate 2, and is a member for positioning a plurality of the substrates 3A, 3B, and 3C. The first positioning portion 10 is a cylindrical member extending upward from the upper surface 6a.

As shown in FIG. 3, in the base plate 2, the second positioning portion 20A is provided at a position corresponding to the vicinity of the edge 3Aa of the substrate 3A. The second positioning portion 20A is a member provided to extend upward from the base plate 2 at a position different from the first positioning portion 10. The second positioning portion 20A is a cylindrical member extending upward from the upper surface 2a. In the base plate 2, the second positioning portion 20B is provided at a position corresponding to the vicinity of the edge 3Bd of the substrate 3B. The second positioning portion 20B is a member provided to extend from the base plate 2 at a position different from the first positioning portion 10. The second positioning portion 20B is a cylindrical member extending upward from the upper surface 2a. In the base plate 2, the second positioning portion 20C is provided at a position corresponding to the vicinity of the edge 3Cd of the substrate 3C (see FIG. 3). The second positioning portion 20C is a member provided to extend from the base plate 2 at a position different from the first positioning portion 10. The second positioning portion 20C is a cylindrical member extending upward from the upper surface 6a.

The substrates 3A, 3B, and 3C have first positioning holes 11A, 11B, and 11C, respectively, inserted with the first positioning portion 10. The first positioning holes 11A, 11B, and 11C are provided at the overlapping portion 9, and are arranged at the same position in the X-Y plane. Each of the substrates 3A, 3B, and 3C has the second positioning holes 12A, 12B, and 12C at positions different from the first positioning hole 11A, 11B, and 11C. As shown in FIG. 5, in the present embodiment, the second positioning hole 12A is inserted with the second positioning portion 20A, and the second positioning holes 12B and 12C are not inserted. The second positioning hole 12B is inserted with the second positioning portion 20B, and the second positioning holes 12A and 12C are not inserted. The second positioning hole 12C is inserted with the second positioning portion 20C, and the second positioning holes 12A and 12B are not inserted.

Next, with reference to FIG. 4, the positional relationship of the positioning portions 10, 20A, 20B, and 20C will be described in more detail. The positions of the positioning portions 10, 20A, 20B, and 20C are not particularly limited, and may be changed as appropriate. As shown in FIG. 4, the first positioning portion 10 is at a position along the edge 3Ab of the substrate 3A, and is disposed near the corner between the edge 3Ad and the edge 3Ab. The first positioning portion 10 is disposed near an end portion of the overhang portion 8 of the substrate 3B on the negative side in the Y-axis direction. The first positioning portion 10 is provided at a position along the edge 3Cd in the substrate 3C, and near the corner with the edge 3Cd.

In the present embodiment, the second positioning portion 20A is disposed at a position separated from the first positioning portion 10 toward the positive side in the X-axis direction. The second positioning portion 20A is disposed in an end portion of the substrate 3A opposite to the first positioning portion 10 in the X-axis direction, that is, in the vicinity of the edge 3Aa. The second positioning portion 20A is disposed at the same position as the first positioning portion 10 in the Y-axis direction. The second positioning portion 20C is disposed at a position separated from the first positioning portion 10 toward the positive side in the X-axis direction. The second positioning portion 20C is disposed at an end portion of the substrate 3C opposite to the first positioning portion 10 in the X-axis direction, that is, at a position closer to the edge 3Ca. The second positioning portion 20C is disposed at the same position as the first positioning portion 10 in the Y-axis direction. Therefore, in a plan view, when a reference line SL1 connecting the center of the first positioning portion 10 and the center of the second positioning portion 20A is set, the reference line SL1 passes through the center of the second positioning portion 20C.

In the present embodiment, the second positioning portion 20B is disposed at a position separated from the first positioning portion 10 toward the negative side in the X-axis direction. The second positioning portion 20B is disposed in an end portion of the substrate 3B opposite to the first positioning portion 10 in the X-axis direction, that is, in the vicinity of the edge 3Bb. The second positioning portion 20B is disposed at a position separated from the first positioning portion 10 toward the negative side in the Y-axis direction. The second positioning portion 20B is disposed at an end portion of the substrate 3B opposite to the first positioning portion 10 in the Y-axis direction, that is, near the edge 3Bd. In a plan view, when a reference line SL2 connecting the center of the first positioning portion 10 and the center of the second positioning portion 20B is set, the reference line SL2 is inclined toward the negative side in the Y-axis direction as it goes toward the negative side in the X-axis direction.

Next, with reference to FIG. 5, shapes of the positioning portions 10, 20A, 20B, and 20C will be described in detail. As shown in FIG. 5, an outer peripheral surface 10a of the first positioning portion 10 has insertion parts 14A, 14B, and 14C that are inserted into the first positioning holes 11A, 11B, and 11C, respectively. The insertion parts 14A, 14B, and 14C are locations facing the first positioning holes 11A, 11B, and 11C in the diameter direction in a state in which assembly of the substrates 3A, 3B, and 3C is completed. The outer peripheral surface 10a of the first positioning portion 10 extends parallel to the extension direction in the insertion parts 14A, 14B and 14C. Here, the vertical direction (Z-axis direction) is the extension direction. The state in which the outer peripheral surface 10a extends parallel to the extension direction is a state in which the shape and size of the outer peripheral surface in a cross section parallel to the X-Y plane are constant in the Z-axis direction.

Thus, the outer diameter of the outer peripheral surface 10a of the first positioning portion 10 is constant in the extension direction in the insertion part 14A, constant in the extension direction in the insertion part 14B and constant in the extension direction in the insertion part 14C. When the first positioning portion 10 is viewed from any one of the X-Y axis directions, the outer peripheral surface 10a is parallel to the extension direction. For example, a state in which the outer peripheral surface 10a is inclined with respect to the extension direction at the insertion parts 14A, 14B, and 14C as in the comparative example shown in the 9B does not correspond to the state of “extending parallel to the extension direction”. The outer peripheral surface in a cross-section parallel to the X-Y plane of the insertion parts 14A, 14B, 14C (and elsewhere) of the first positioning portion 10 is circular. However, the cross-sectional shape is not particularly limited, and may be an ellipse, an oval, a polygon, or the like.

In the present embodiment, in the first positioning portion 10, each of the insertion parts 14A, 14B, and 14C is configured to have the same diameter in each other. The first positioning portion 10 extends from the insertion part 14C upwards to the distal end portion 10b in the extension direction while maintaining the same diameter. Thus, the first positioning portion 10 has a cylindrical shape. The distal end portion 10b of the first positioning portion 10 is formed in a taper shape. The distal end portion 10b is inclined so as to be tapered off with a diameter decreasing upward. However, the distal end portion 10b may have a rounded R shape.

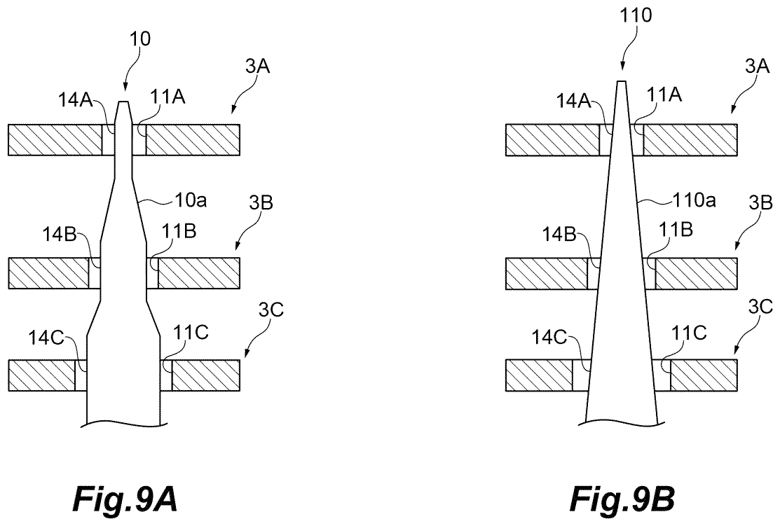

Similarly to the first positioning portion 10, the second positioning portions 20A, 20B, and 20C have cylindrical shapes. That is, the outer peripheral surface 20a of the second positioning portions 20A, 20B, and 20C extends parallel to the extension direction. However, the structure of the outer peripheral surface 20a of the second positioning portions 20A, 20B and 20C is not particularly limited as long as the positioning of the substrates 3A, 3B and 3C can be performed, and a stepped shape as shown in FIG. 9A or an inclined shape as shown in FIG. 9B may be adopted. distal end portions 20b of the second positioning portions 20A, 20B and 20C are formed into a taper shape.

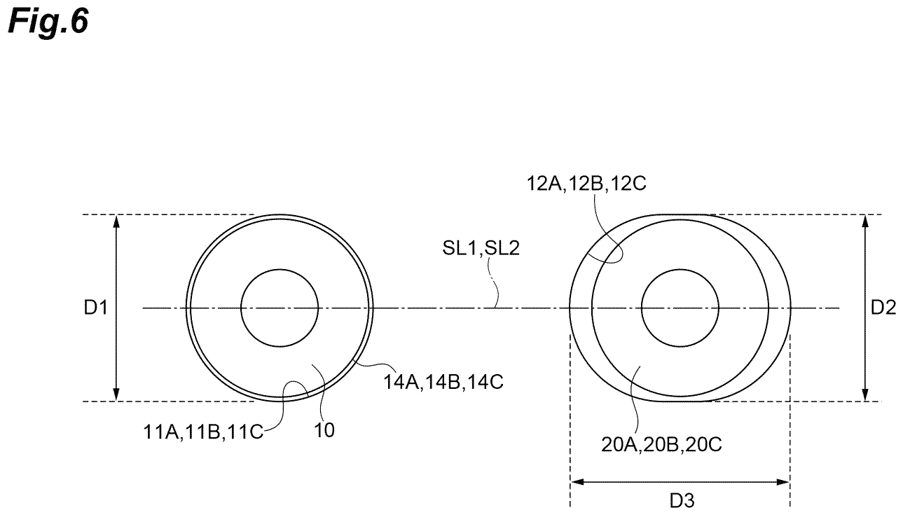

Next, with reference to FIG. 6, the sizes and shapes of positioning holes 11A, 11B, 11C, 12A, 12B, and 12C will be described. The diameter of the positioning portions 10, 20A, 20B, and 20C is not particularly limited, but may be 2 to 6 mm. The diameter of the first positioning portion 10 may be the same as or different from the diameters of the second positioning portions 20A, 20B, and 20C. As shown in FIG. 6, the first positioning holes 11A, 11B, and 11C have circular shapes when viewed from the vertical direction. A diameter D1 of the first positioning holes 11A, 11B, and 11C is not particularly limited as long as the first positioning portion 10 can be inserted into the positioning holes 11A, 11B, and 11C and excessive rattling in positioning can be suppressed, but for example, the diameter D1 may be in a range of 100 to 120% of the diameter of the insertion parts 14A, 14B, and 14C of the first positioning portion 10.

Each of the second positioning holes 12A, 12B, and 12C has a shape extending along the reference lines SL1 or SL2 when viewed from the vertical direction. In the example shown in FIG. 6, each of the second positioning holes 12A, 12B, and 12C has an oval shape extending along the reference line SL1 or SL2. However, the second positioning holes 12A, 12B, and 12C may have elliptical shapes. A diameter D2 in the short direction of the second positioning holes 12A, 12B, and 12C may be the same ratio as the first positioning holes 11A, 11B, and 11C. A diameter D3 of the second positioning holes 12A, 12B, and 12C in the longitudinal direction is not particularly limited as long as it is in a range in which a margin can be provided in inserting, and for example, the diameter D3 may be in a range of 100 to 200% of the diameter D2. Each of the second positioning holes 12A, 12B, and 12C may be configured to have the same shape and size as each other.

The substrate 3A, 3B, and 3C positioned by the first positioning portion 10 tend to move in the direction of rotation about the first positioning portion 10. Therefore, the second positioning holes 12A, 12B, and 12C tend to rotate in a direction orthogonal to the reference lines SL1 and SL2. On the other hand, each of the second positioning holes 12A, 12B, and 12C has a short direction in a direction orthogonal to the reference line SL1 or SL2. Therefore, the second positioning holes 12A, 12B, and 12C can be prevented from moving in a direction orthogonal to the reference line SL1 and the SL2. On the other hand, each of the second positioning holes 12A, 12B, and 12C has a longitudinal direction in a direction in which the reference line SL1 or SL2 extend. Therefore, it is possible to secure a margin when the second positioning portions 20A, 20B, and 20C are inserted into the second positioning holes 12A, 12B, and 12C.

Next, functions and effects of the substrate structure 100 according to the present embodiment will be described.

The substrate structure 100 according to the present embodiment includes the first positioning portion 10 provided to extend from the base plate 2 and position the substrates 3A, 3B, and 3C. The substrates 3A, 3B, and 3C have the first positioning hole 11A, 11B, and 11C, respectively, to be inserted with the first positioning portion 10. Therefore, by inserting the first positioning portion 10 into the first positioning holes 11A, 11B, and 11C of the substrate 3A, 3B, and 3C, the substrate 3A, 3B, and 3C can be positioned with reference to the first positioning portion 10.

Here, with reference to FIG. 9B, a comparative example will be described. In FIG. 9B, a first positioning portion 110 for positioning each of the substrates 3A, 3B, and 3C has a taper shape. In this case, the position of an outer peripheral surface 110a of the first positioning portion 110 changes in the vertical direction at each of the insertion parts 14A, 14B, and 14C of the positioning holes 11A, 11B, and 11C of the substrates 3A, 3B, and 3C. In this case, it is likely to become complicated of reference setting in designing and become difficult to process the member with high accuracy.

In contrast, in the substrate structure 100 according to the present embodiment, the outer peripheral surface 10a of the first positioning portion 10 extends parallel to the extension direction in the insertion parts 14A, 14B, and 14C, which are inserted into the first positioning holes 11A, 11B, and 11C, respectively. In this case, at the insertion parts of the first positioning holes 11A, 11B, and 11C of each of the substrates 3A, 3B, and 3C, the outer peripheral surface 10a of the first positioning portion 10 has a constant structure in the vertical direction. In this case, when the reference positions of the first positioning portion 10, the first positioning holes 11A, 11B, and 11C are set at the time of designing, the reference setting can be easily performed. In addition, when the member is processed, the processing can be easily and accurately performed. Thus, the substrates 3A, 3B and 3C can be easily manufactured while being accurately positioned.

In the first positioning portion 10, each of the insertion parts 14A, 14B, and 14C may be configured to have the same diameter as each other. In this case, design and processing are facilitated.

The distal end portion 10b of the first positioning portion 10 may be formed in a taper shape. In this case, the distal end portion 10b of the first positioning portion 10 can guide the first positioning holes 11A, 11B, and 11C of the substrate 3A, 3B, and 3C.

Each of the substrate 3A, 3B, and 3C may have the second positioning holes 12A, 12B, and 12C at positions different from the first positioning holes 11A, 11B, and 11C, and the second positioning holes 12A, 12B, and 12C may be inserted with the second positioning portions 20A, 20B, and 20C provided to extend from the base plate 2 at positions different from the first positioning portion 10. In this case, by inserting the second positioning portions 20A, 20B, and 20C into the second positioning holes 12A, 12B, and 12C of the substrates 3A, 3B, and 3C, it is possible to prevent the rotation of the substrates 3A, 3B, and 3C around the first positioning portion 10 by the second positioning portions 20A, 20B, and 20C.

Each of the second positioning holes 12A, 12B, and 12C may be configured to have the same shape and size as each other. In this case, since the second positioning holes 12A, 12B and 12C can be formed by the same designing contents and the same processing method in each of the substrates 3A, 3B and 3C, designing and processing can be easily performed.

The present disclosure is not limited to the embodiments described above.

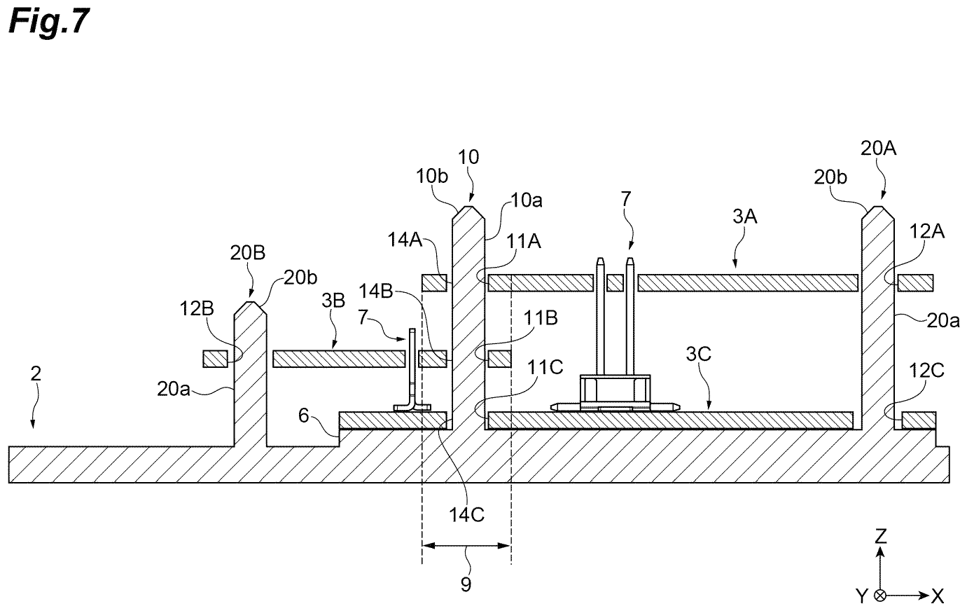

In the above-described embodiment, one second positioning portion 20A, 20B, and 20C is provided for each of the substrate 3A, 3B, and 3C, respectively. Alternatively, the second positioning portion may be shared by a plurality of substrates. For example, as shown in FIG. 7, the second positioning portion 20C for the substrate 3C may be omitted. Also, the substrate 3C may extend to the second positioning portion 20A side and form the second positioning hole 12C to be inserted with the second positioning portion 20A. According to the structure shown in FIG. 7, the second positioning portion 20A can be used as a positioning portion shared by the substrates 3A and 3C. Further, the second positioning portion may be shared by other combinations without being limited to FIG. 7.

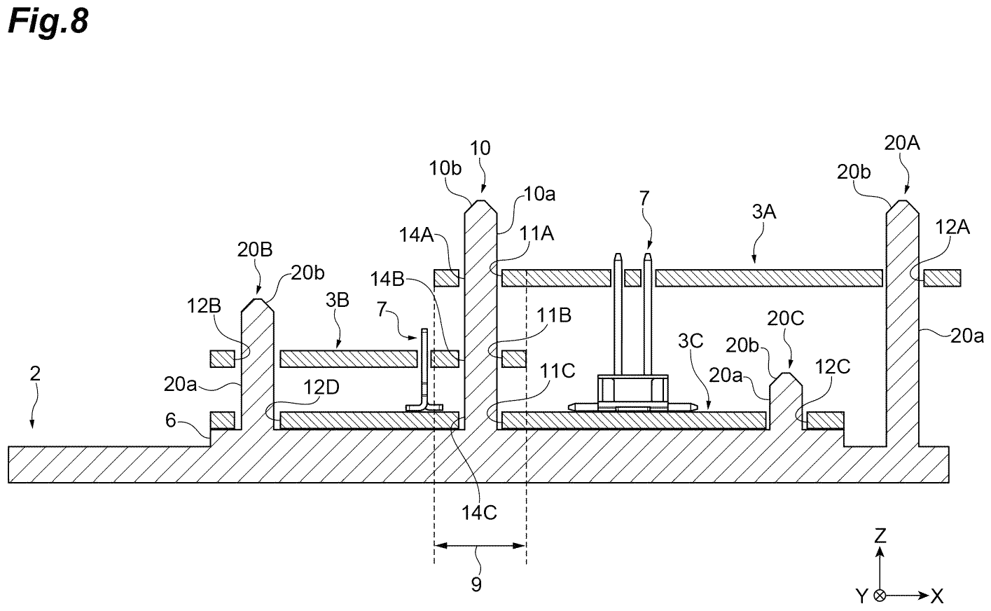

In addition, the substrate may be positioned by a plurality of second positioning portions. For example, as shown in FIG. 8, the substrate 3C may extend to the second positioning portion 20B side and form a second positioning hole 12D that is inserted with the second positioning portion 20B. According to the structure shown in FIG. 8, the substrate 3C can be positioned at two positions of the second positioning portion 20C and thee second positioning portion 20B.

In addition, in the first positioning portion 10, each of the insertion parts 14A, 14B, and 14C may not have the same diameter. For example, as shown in the 9A, in the first positioning portion 10, each of the insertion parts 14A, 14B, and 14C may be configured in a stepped shape such that the diameter increases from the distal end side. The insertion part 14A positioned uppermost has the smallest diameter and the insertion part 14C positioned lowermost has the largest diameter. In this case, since the root side (the base plate 2 side) of the first positioning portion 10 can be made thicker than the distal end side, the strength of the first positioning portion 10 can be improved. In the structure shown in FIG. 9A, in contrast to the structure shown in FIG. 9B, the outer peripheral surface 10a extends parallel to the extension direction at least at each insertion parts 14A, 14B, and 14C. Although the diameter of the part between the insertion parts 14A, 14B, and 14C increases in a tapered manner, the diameter may increase horizontally.

The size, arrangement, and quantity of each component are not limited to those of the above-described embodiment, and can be changed as appropriate. For example, in the above-described embodiment, three substrates are positioned, but two substrates or four or more substrates may be positioned.

What is claimed is:

1. A substrate structure comprising:
a base plate;
three or more substrates; and
a first positioning portion disposed to extend from the base plate and positioning a plurality of the substrates;
wherein each of the plurality of substrates has a first positioning hole to be inserted with the first positioning portion; and
wherein an outer peripheral surface of the first positioning portion extending parallel to an extension direction at each of insertion parts inserted into each of the first positioning holes.

2. The substrate structure according to claim 1, wherein each of the insertion parts in the first positioning portion has the same diameter.

3. The substrate structure according to claim 1, wherein each of the insertion parts in the first positioning portion is formed in a stepped shape such that diameters increase sequentially from the distal end side.

4. The substrate structure according to claim 1, wherein a distal end of the first positioning portion is formed in a taper shape.

5. The substrate structure according to claim 1, wherein each of the substrates has a second positioning hole at a position different from the first positioning hole, a second positioning portion provided to extend from the base plate at a position different from the first positioning portion is inserted into the second positioning hole.

6. The substrate structure according to claim 5, wherein each of the second positioning holes has the same shape and the same size.
